(19) United States
(12) Patent Application Publication
(10) Pub. No.: US 2020/0144547 A1
(43) Pub. Date: May 7, 2020

(54) DISPLAY PANEL AND DISPLAY DEVICE

(71) Applicants: Kai WAN, Wuhan, Hubei (CN); Xiaohua ZHONG, Wuhan, Hubei (CN)

(72) Inventors: Kai WAN, Wuhan, Hubei (CN); Xiaohua ZHONG, Wuhan, Hubei (CN)

(21) Appl. No.: 16/336,123

(22) PCT Filed: Oct. 12, 2018
(86) PCT No.: PCT/CN2018/110109

§ 371 Date: Mar. 25, 2019

(30) Foreign Application Priority Data
Jul. 2, 2018 (CN) 201810708417.1

(51) Int. Cl. H01L 51/52; H01L 27/32

(52) U.S. Cl. CPC H01L 51/5262; H01L 51/5237; H01L 2251/5369; H01L 2227/323; H01L 27/3246

(57) ABSTRACT

A display panel and a display device are provided. The display panel includes a substrate, a thin film transistor layer, a light emitting device layer, a thin film encapsulation layer and a particle layer. A particle layer consisted of silver particles is disposed between the thin film transistor layer and the thin film encapsulation layer, and the density of state of photons and the spontaneous emission rate of excitons are increased so that the luminous efficiency of the OLED display panel is improved.

### BACKGROUND OF THE INVENTION

### Field of Invention

The present invention relates to a field of display, and more particularly to a field of a display panel and a display device.

### Description of Prior Art

OLED display devices include passive matrix type light emitting diodes (PMOLED) and active matrix type light emitting diodes (AMOLED), namely direct addressing and thin film transistor (TFT) matrix addressing. The AMOLED has pixels arranged in an array that belongs to an active display type and has high luminous efficiency, and is generally used as a high resolution large-sized display device.

The luminous efficiency of an AMOLED device includes internal quantum efficiency (IQE) and external quantum efficiency (EQE), which are represented by Nᵢₙₜ and Nₑₓₜ, respectively.

The relationship between Nᵢₙₜ and Nₑₓₜ is described as follows:

Nₑₓₜ=Nᵢₙₜ×Nₒᵤₜ (Nₒᵤₜ is light extraction efficiency) (1)

It can be learned from equation (1) that the external quantum efficiency of the AMOLED panel is related to the quantum efficiency and light extraction rate of the AMOLED panel.

The correlation of internal quantum efficiency is described as follows:

Nᵢₙₜ=γ·χ·ηᵣ (2)

where γ is the carrier balance factor, χ is the exciton spin factor and ηᵣ is the photoluminescence quantum efficiency of the organic luminescent material. In addition, the higher ηᵣ is, the higher the internal quantum efficiency is.

The photoluminescence quantum efficiency ηᵣ reflects the probability of exciton radiation recombination, which can be expressed as follows:

$${η}_{r} = \frac{{K}_{r}}{{K}_{r} + {K}_{n}} = \frac{radiation photon numbers}{generate exciton numbers} \qquad ( 3 )$$

where Kᵣ represents the rate of exciton radiation transition, and Kₙ represents the rate of non-radiative transition.

Therefore, increasing the rate of exciton radiation transition can effectively increase ηᵣ and thereby the internal quantum efficiency of the AMOLED device is improved. According to the Purcell effect, the rate of spontaneous radiation transition of an exciton is proportional to the density of states of the photon. Accordingly, increasing the density of states of photons is the key to solve the problem.

### SUMMARY OF THE INVENTION

The present invention provides a display panel and a display device to solve the technical problem that the density of states of photons in the existing display panel is low.

In order to solve the above problems, the technical solutions provided by the present invention are described as follows:

In one embodiment of the present invention, a display panel is provided by the present invention includes a substrate, a thin film transistor layer formed on the substrate, a light emitting device layer formed on the thin film transistor layer, a thin film encapsulation layer formed on the light emitting device layer and a particle layer formed between the thin film transistor layer and the thin film encapsulation layer, wherein the particle layer includes at least two nanoparticles.

In one embodiment of the display panel of the present invention, the light emitting device layer comprises an anode layer disposed on the thin film transistor layer, an emitting layer disposed on the anode layer and a cathode layer disposed on the emitting layer, and the particle layer is disposed between the anode layer and the emitting layer or/and the thin film transistor layer.

In one embodiment of the display panel of the present invention, the light emitting device layer includes an anode layer disposed on the thin film transistor layer, an emitting layer disposed on the anode layer and a cathode layer disposed on the emitting layer, and the particle layer is disposed between the cathode layer and the emitting layer or/and the thin film encapsulation layer.

In one embodiment of the display panel of the present invention, the thin film encapsulation layer is made by alternatively stacking at least one organic layer and at least one inorganic layer, and the particle layer is disposed on the organic layer or the inorganic layer of the thin film encapsulation layer.

In one embodiment of the display panel of the present invention, the display panel further includes a pixel definition layer disposed on the thin film transistor, and the particle layer is disposed on the inclined plane that is positioned between the pixel definition layer and the emitting layer.

In one embodiment of the display panel of the present invention, the particle layer includes at least one nanoparticle layer.

In one embodiment of the display panel of the present invention, each of the nanoparticle has a different shape.

In one embodiment of the display panel of the present invention, each smallest circumscribed circle of the nanoparticles has a different size.

In one embodiment of the display panel of the present invention, a spacing interval between any two adjacent nanoparticles is not less than zero.

Furthermore, a display device is provided by the present invention includes a display panel and a touch layer, a polarizing plate layer and a cover layer on the display panel. The displayer panel includes a substrate, a thin film transistor layer formed on the substrate, a light emitting device layer formed on the thin film transistor layer, a thin film encapsulation layer formed on the light emitting device layer and a particle layer formed between the thin film transistor layer and the thin film encapsulation layer. The particle layer includes at least two nanoparticles.

In one embodiment of the display device of the present invention, the light emitting device layer includes an anode layer disposed on the thin film transistor layer, an emitting layer disposed on the anode layer and a cathode layer disposed on the emitting layer, and the particle layer is disposed between the anode layer and the emitting layer or/and the thin film transistor layer.

In one embodiment of the display device of the present invention, the light emitting device layer includes an anode layer disposed on the thin film transistor layer, an emitting layer disposed on the anode layer and a cathode layer disposed on the emitting layer, and the particle layer is disposed between the cathode layer and the emitting layer or/and the thin film encapsulation layer.

In one embodiment of the display device of the present invention, the thin film encapsulation layer is made by alternatively stacking at least one organic layer and at least one inorganic layer, and the particle layer is disposed on the organic layer or the inorganic layer of the thin film encapsulation layer.

In one embodiment of the display device of the present invention, the display panel further includes a pixel definition layer disposed on the thin film transistor, and the particle layer is disposed on the inclined plane that is positioned between the pixel definition layer and the emitting layer.

In one embodiment of the display device of the present invention, the particle layer includes at least one nanoparticle layer.

In one embodiment of the display device of the present invention, each of the nanoparticle has a different shape.

In one embodiment of the display device of the present invention, each smallest circumscribed circle of the nanoparticles has a different size.

In one embodiment of the display device of the present invention, a spacing interval between any two adjacent nanoparticles is not less than zero.

The beneficial effect of the present application is that the present invention provides a particle layer between the thin film transistor layer and the thin film encapsulation layer, and the particle layer includes silver nanoparticles. The density of state of photons and the spontaneous emission rate of excitons are increased through the SPR effect of the surface of the silver nanoparticles, so that the luminous efficiency of the OLED display panel is improved. Moreover, the light reflection effect of the silver nanoparticle layer can reduce the loss of light and improve the light extraction rate from the OLED display panel.

### BRIEF DESCRIPTION OF THE DRAWINGS

In order to more clearly illustrate embodiments or technical solutions in the present invention, the drawings used in the description of the embodiments or current technology will be briefly described below. Obviously, the drawings in the following description are merely some embodiments of the present invention. A person skilled in the art may also obtain other drawings without any creative efforts.

FIG. 1 is a schematic of display panel structure according to the first embodiment of the present invention.

FIG. 2 is a schematic of display panel structure according to the second embodiment of the present invention.

FIG. 3 is a schematic of display panel structure according to the third embodiment of the present invention.

FIG. 4 is a schematic of display panel structure according to the fourth embodiment of the present invention.

FIG. 5 is a schematic of display panel structure according to the fifth embodiment of the present invention.

FIG. 6 is a first distribution diagram of nanoparticles in the particle layer according to one embodiment of the present invention.

FIG. 7 is a second distribution diagram of nanoparticles in the particle layer according to one embodiment of the present invention.

FIG. 8 is a third distribution diagram of nanoparticles in the particle layer according to one embodiment of the present invention.

FIG. 9 is a fourth distribution diagram of nanoparticles in the particle layer according to one embodiment of the present invention.

FIG. 10 is a schematic of a display panel's layer structure according to the sixth embodiment of the present invention.

### DETAILED DESCRIPTION OF THE PREFERRED EMBODIMENTS

The following description of the embodiments is provided by reference to the following drawings. Directional terms mentioned in this application, such as “up,” “down,” “forward,” “backward,” “left,” “right,” “inside,” “outside,” “side,” etc., are merely indicated the direction of the drawings. Therefore, the directional terms are used for illustrating and understanding of the application rather than limiting thereof. In the figures, elements with similar structure are indicated by the same reference numerals.

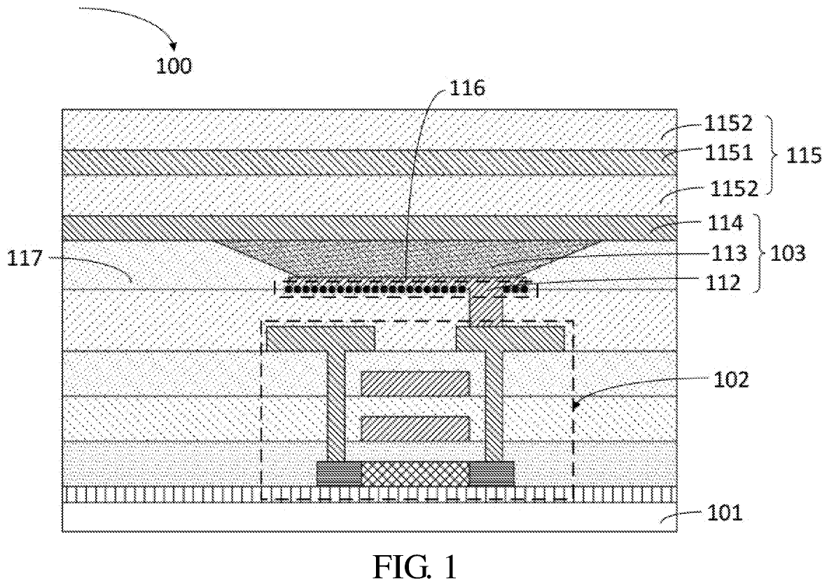

FIG. 1 is a schematic of a display panel's layer structure according to the first embodiment of the present invention. The display panel 100 includes a substrate 101, a thin film transistor layer 102, a light emitting device layer 103, a thin film encapsulation layer 115 and a particle 116. The substrate 101 is selected from one of glass substrate, quartz substrate and resin substrate. The thin film transistor layer 102 is formed on the substrate 101. The thin film transistor layer 102 includes an etching stop layer type, a back channel etch type or a top gate thin film transistor type.

The thin film transistor layer 102 includes a structure such as an etch barrier layer type, a back channel etch type or a top gate thin film transistor type, and is not particularly limited. The top gate thin film transistor type is described as follows according to the embodiment of the present invention.

The thin film transistor layer 102 includes a buffer layer, an active layer, a gate insulating layer, a first metal layer (gate layer), an interlayer insulating layer, a second metal layer, a second interlayer insulating layer, a source/drain and a planar layer.

The light emitting device layer 103 includes an anode layer 112 disposed on the thin film transistor layer 102, an emitting layer disposed on the anode layer and a cathode layer disposed on the emitting layer.

The anode layer 112 is formed on the planar layer. The anode layer includes at least two anodes arranged in an array, and the anode layer 112 is mainly used to provide holes for absorbing electrons.

In one embodiment of the present invention, the light emitting device is a top-emitting organic light emitting device, and the light emitting device is a white light emitting device that emits white light.

In one embodiment of the present invention, an anode layer 112 is a non-transparent light blocking layer. An emitting layer 113 is formed on the anode layer 112, and the adjacent light emitting device layer 103 is isolated by a pixel definition layer 117. A cathode layer 114 is formed on the light emitting device layer 103, and the cathode layer 114 is used to provide the electrons.

In one embodiment of the present invention, the cathode layer 114 is made of transparent material, and light generated from the emitting layer is projected outward through the cathode layer 114. The thin film encapsulation layer 115 is formed on the cathode layer 114. The thin film encapsulation layer 115 mainly functions as a moisture blocking so as to prevent external water vapor.

The thin film encapsulation layer 115 mainly functions as a water blocking oxygen barrier to prevent external water vapor from eroding the light emitting device layer. The thin film encapsulation layer 115 is made by alternatively stacking at least one organic layer and at least one inorganic layer.

Referring to FIG. 1, the display panel 100 further includes at least one particle layer 116, and the particle 116 is formed between the thin film transistor layer 102 and the thin film encapsulation layer.

In one embodiment of the present invention, the particle layer 116 is composed of nanoparticles. Furthermore, the nanoparticles are silver nanoparticles.

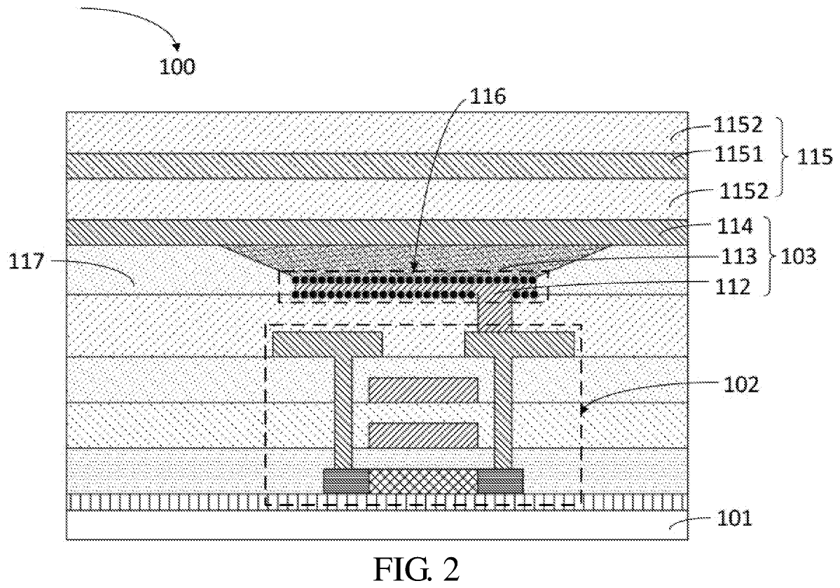

Referring to FIG. 2, it is a schematic of display panel structure according to the second embodiment of the present invention. The particle layer 116 may be disposed on an upper surface or a lower surface of the anode layer 112. That is, the particle layer 116 is disposed between the anode layer 112 and the light emitting device layer 103, or/and is disposed between the anode layer 112 and the thin film transistor layers 102.

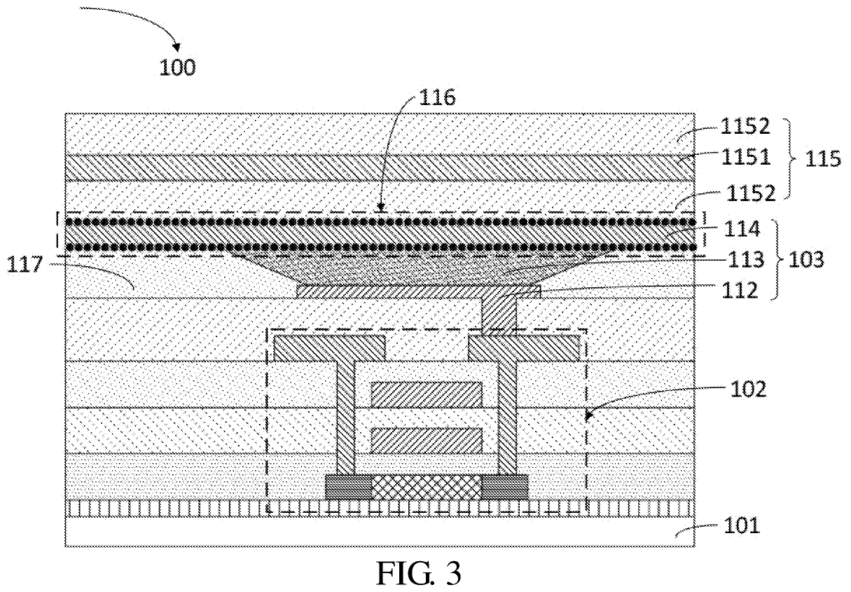

Referring to FIG. 3, it is a schematic of display panel structure according to the third embodiment of the present invention. The particle layer 116 may be disposed between the cathode layer 114 and the emitting layer 113, or/and is disposed between the cathode layer 114 and the thin film encapsulation layer 115.

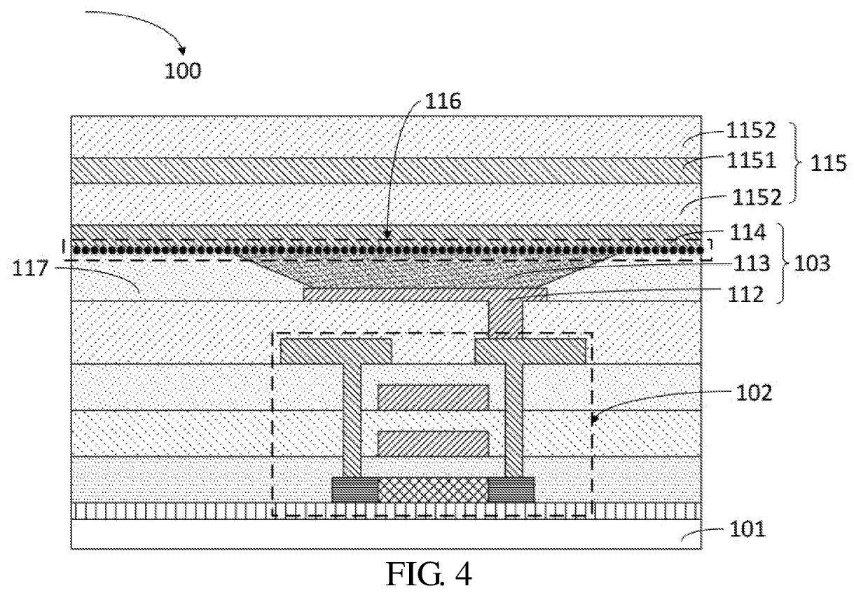

Referring to FIG. 4, it is a schematic of display panel structure according to the fourth embodiment of the present invention. The particle layer 116 is formed between the cathode layer 114 and the light emitting device layer 103. A silver nanoparticle layer is vaporized on the cathode layer by a thermal evaporation. That is, the silver nanoparticle layer is formed between the cathode layer 114 and the second functional layer of the light emitting device layer 103

When the surface of the silver nanoparticles is excited, the spontaneous emission rate of the excitons is accelerated and the internal quantum efficiency is improved. Theoretically, the silver nanoparticles are close to the emitting layer, the better internal quantum efficiency is obtained. However, it is difficult to form silver nanoparticles near the emitting layer and does not have a certain repeatability.

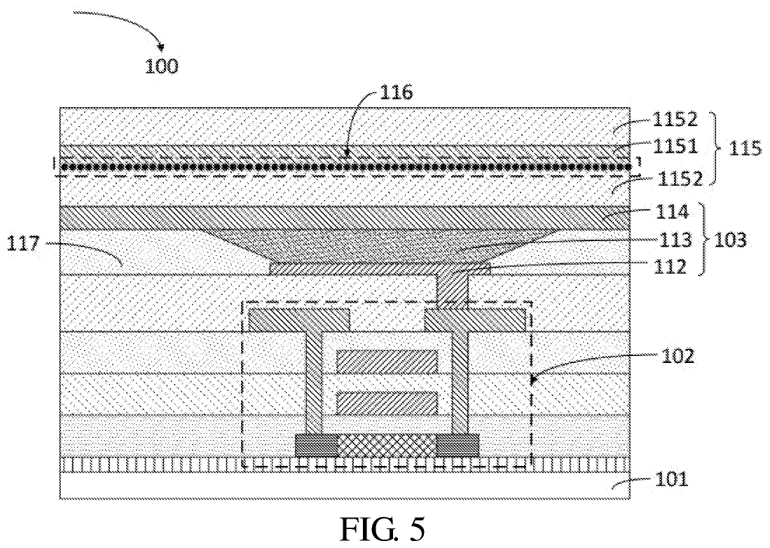

Referring to FIG. 5, it is a schematic of display panel structure according to the fifth embodiment of the present invention. The particle layer 116 is formed on the inorganic layer of the thin film encapsulation layer 115. Also, the particle 116 is formed on the organic layer 1151 of the thin film encapsulation layer 115 (not shown).

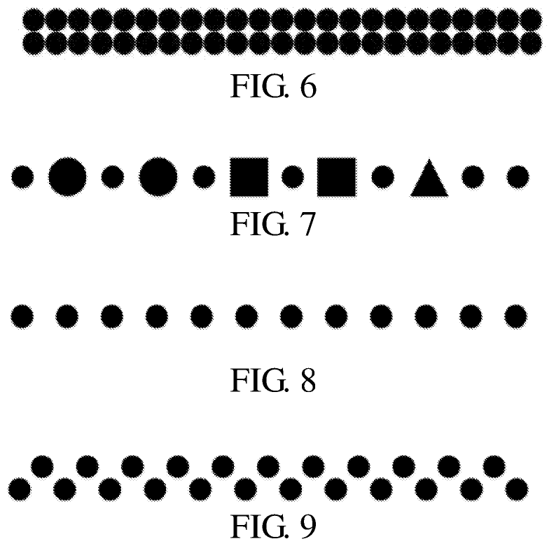

Referring to FIG. 6 to FIG. 9, they are distribution diagrams of nanoparticles in the particle layer according to one embodiment of the present invention.

Referring to FIG. 6, the particle layer 116 includes two nanoparticle layers. The specific number of the nanoparticle layers is determined by the actual increased photon density.

Referring to FIG. 7, the shape of the two adjacent nanoparticles and the size of the smallest circumscribed circle may be the same or different. The actual nanoparticles are different based on the factors such instrument and human error.

In one embodiment of the present invention, the nanoparticles may be regular shapes such as sphere, cube, cuboid or triangle, or other irregular shapes.

Referring to FIG. 7 and FIG. 8, the spacing interval between any two adjacent nanoparticles is “a,” and the “a” is greater than or equal to zero.

When the “a” is zero, two adjacent nanoparticles are closely connected. When the “a” is greater than 0, there is a certain space between the two adjacent nanoparticles.

Referring to FIG. 9, the adjacent two layers of the nanoparticles may also be alternatively spaced.

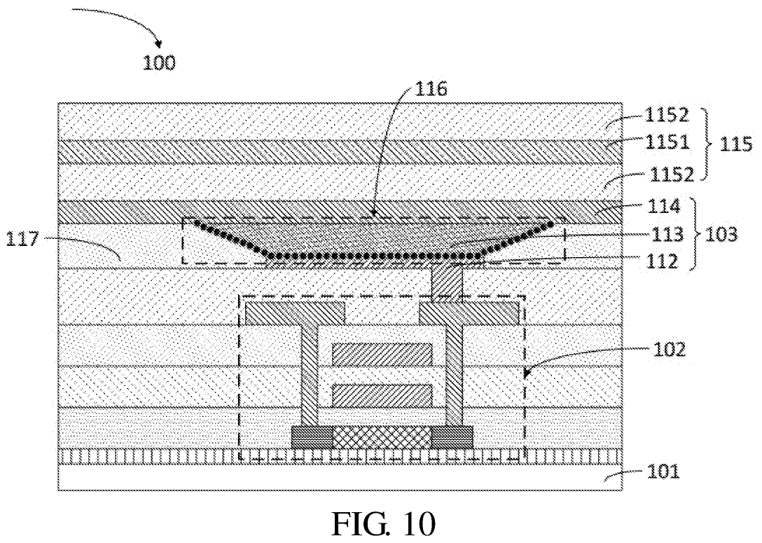

Referring to FIG. 10, it is a schematic of a display panel's layer structure according to the sixth embodiment of the present invention. The nanoparticles are disposed on the anode layer 112 and inclined plane that is positioned between the pixel definition layer 117 and the emitting layer 113.

In one embodiment of the present invention, the particle layer 116 is a groove type.

In one embodiment of the present invention, when silver nanoparticles are located between the emitting layer and functional layer (not shown), the photon density is maximumly increased, but the process is more difficult. When the silver nanoparticles are disposed away the emitting layer, the photon density is reduced, but the process is much simple.

In one embodiment of the present invention, the nanoparticles are disposed on the upper or lower surface of the anode layer 112. Alternatively, the nanoparticles are disposed on the upper or lower surface of the cathode layer 114.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

The present invention also provides a display device including the above display panel and a touch layer, a polarizer layer and a cover layer on the display panel.

The present invention provides a display panel and a display device, the display panel includes a substrate, a thin film transistor layer, a light emitting device layer, a thin film encapsulation layer, and a particle layer. The present invention provides a particle layer between the thin film transistor layer and the thin film encapsulation layer, and the particle layer includes silver nanoparticles. That is, the density of state of photons and the spontaneous emission rate of excitons are increased through the SPR effect of the surface of the silver nanoparticles, so that the luminous efficiency of the OLED display panel is improved. Moreover, the light reflection effect of the silver nanoparticle layer can reduce the loss of light and improve the light extraction rate from the OLED display panel.

In the above, although the present application has been described in the above preferred embodiments, the preferred embodiments are not intended to limit the application. A person skilled in the art may make various modifications without departing from the spirit and scope of the application. The scope of the present application is determined by claims.

What is claimed is:

1. A display panel, comprising:
a substrate;
a thin film transistor layer formed on the substrate;
a light emitting device layer formed on the thin film transistor layer;
a thin film encapsulation layer formed on the light emitting device layer; and
a particle layer formed between the thin film transistor layer and the thin film encapsulation layer, wherein the particle layer comprises at least two nanoparticles.

2. The display panel according to claim 1, wherein the light emitting device layer comprises an anode layer disposed on the thin film transistor layer, an emitting layer disposed on the anode layer and a cathode layer disposed on the emitting layer, and the particle layer is disposed between the anode layer and the emitting layer or/and the thin film transistor layer.

3. The display panel according to claim 1, wherein the light emitting device layer comprises an anode layer disposed on the thin film transistor layer, an emitting layer disposed on the anode layer and a cathode layer disposed on the emitting layer, and the particle layer is disposed between the cathode layer and the emitting layer or/and the thin film encapsulation layer.

4. The display panel according to claim 1, wherein the thin film encapsulation layer is made by alternatively stacking at least one organic layer and at least one inorganic layer, and the particle layer is disposed on the organic layer or the inorganic layer of the thin film encapsulation layer.

5. The display panel according to claim 1, wherein the display panel further comprises a pixel definition layer disposed on the thin film transistor, and the particle layer is disposed on the inclined plane that is positioned between the pixel definition layer and the emitting layer.

6. The display panel according to claim 1, wherein the particle layer comprises at least one nanoparticle layer.

7. The display panel according to claim 6, wherein each of the nanoparticle has a different shape.

8. The display panel according to claim 6, wherein each smallest circumscribed circle of the nanoparticles has a different size.

9. The display panel according to claim 6, wherein a spacing interval between any two adjacent nanoparticles is not less than zero.

10. A display device, comprising a display panel and a touch layer, a polarizing plate layer and a cover layer on the display panel, wherein the display panel comprises:
a substrate;
a thin film transistor layer formed on the substrate;
a light emitting device layer formed on the thin film transistor layer;
a thin film encapsulation layer formed on the light emitting device layer; and
a particle layer formed between the thin film transistor layer and the thin film encapsulation layer, wherein the particle layer comprises at least two nanoparticles.

11. The display device according to claim 10, wherein the light emitting device layer comprises an anode layer disposed on the thin film transistor layer, an emitting layer disposed on the anode layer and a cathode layer disposed on the emitting layer, and the particle layer is disposed between the anode layer and the emitting layer or/and the thin film transistor layer.

12. The display device according to claim 10, wherein the light emitting device layer comprises an anode layer disposed on the thin film transistor layer, an emitting layer disposed on the anode layer and a cathode layer disposed on the emitting layer, and the particle layer is disposed between the cathode layer and the emitting layer or/and the thin film encapsulation layer.

13. The display device according to claim 10, wherein the thin film encapsulation layer is made by alternatively stacking at least one organic layer and at least one inorganic layer, and the particle layer is disposed on the organic layer or the inorganic layer of the thin film encapsulation layer.

14. The display device according to claim 10, wherein the display panel further comprises a pixel definition layer disposed on the thin film transistor, and the particle layer is disposed on an inclined plane that is positioned between the pixel definition layer and the emitting layer.

15. The display device according to claim 10, wherein the particle layer comprises at least one nanoparticle layer.

16. The display device according to claim 15, wherein each of the nanoparticle has a different shape.

17. The display device according to claim 15, wherein each smallest circumscribed circle of the nanoparticles has a different size.

18. The display device according to claim 15, wherein a spacing interval between any two adjacent nanoparticles is not less than zero.
